(19) United States
(12) Patent Application Publication
(10) Pub. No.: US 2017/0284386 A1
(43) Pub. Date: Oct. 5, 2017

(54) CONDITION MONITORING DEVICE AND CONDITION MONITORING METHOD FOR EXTRACTED-GAS COMPRESSION SYSTEM, AND EXTRACTED-GAS COMPRESSION SYSTEM

(71) Applicant: MITSUBISHI HEAVY INDUSTRIES, LTD., Tokyo (JP)

(72) Inventors: Akihiro NAKANIWA, Tokyo (JP); Minoru MATSUO, Tokyo (JP); Takaaki KAIKOGI, Tokyo (JP)

(73) Assignee: MITSUBISHI HEAVY INDUSTRIES, LTD., Tokyo (JP)

(21) Appl. No.: 15/506,829

(22) PCT Filed: Nov. 17, 2015
(86) PCT No.: PCT/JP2015/082232

§ 371 Date: Feb. 27, 2017

(30) Foreign Application Priority Data
Mar. 19, 2015 (JP) 2015-055941
Mar. 19, 2015 (JP) 2015-055942

(51) Int. Cl. F04B 49/06; H01J 37/32; G05B 23/02; G06F 11/25; F04D 25/06; F04D 27/00

(52) U.S. Cl. CPC F04B 49/065; F04D 25/0686; F04D 27/001; G05B 23/0243; G05B 23/0283; G06F 11/25; H01J 37/32935; F04B 51/00

(57) ABSTRACT

A condition monitoring device for an extracted-gas compression system including a compressor which increases pressure of extracted gas includes: a sensor for detecting a state quantity of the extracted gas flowing into the compressor; an erosion progression level calculation unit for calculating an erosion progression level of the compressor on the basis of the state quantity of the extracted gas; and a service life evaluation unit for evaluating a service life of the compressor on the basis of the erosion progression level of the compressor.

### TECHNICAL FIELD

The present disclosure relates to a condition monitoring device and a condition monitoring method for an extracted-gas compression system and to an extracted-gas compression system.

### BACKGROUND

For extracting ocean floor resources such as oil or natural gas, compressors are used for increasing the pressure of a gas component in extracted resource and then sending the pressurized gas component to an onshore facility or a floating facility on the sea.

For example, the following configuration is described in Non Patent Document 1. Specifically, gas liquid separation, for separation into a gas component and a liquid component, is performed on the sea floor for natural gas. The natural gas is extracted in a gas-liquid mixture state from a gas well under the sea floor. Then, the pressure of gas component is increased by a compressor, so the gas can be sent to an onshore facility.

### CITATION LIST

### Non Patent Literature

Non Patent Document 1: Turbomachinery International, September/October 2014, p. 18-24

### SUMMARY

### Technical Problem

The compressor has a specification determined on the basis of its operation range (use condition). More specifically, the specification of the compressor is determined in accordance with a designed service life based on an estimated predetermined use condition. The condition is related to a type and a flowrate of gas flowing into the compressor, compressor rotational speed, and the like.

Unfortunately, an extracted-gas compression system deals with extracted gas with various properties, and thus the operation range of the compressor is inconsistent. For example, the particle size and the hardness of foreign matters in the extracted gas might change as operation time elapses. Thus, the compressor might have a service life shorter than the designed service life the extracted-gas compression system.

In many cases, the extracted-gas compression system is used in offshore plants. When the compressor in the offshore plant fails, preparation for the new compressor takes time, and thus the plant becomes inoperable during the preparation. In particular, when the extraction takes place on the sea floor, it takes extremely long time for removing and installing the compressor, rendering the plant inoperable for a long time.

Non Patent Document 1 does not mention about a method of evaluating the service life of the compressor in the extracted-gas compression system.

An object of at least some embodiments of the present invention is to provide a condition monitoring device and a condition monitoring method for an extracted-gas compression system and an extracted-gas compression system in which a state of a compressor can be monitored on the basis of a change in a state quantity of extracted gas.

### Solution to Problem

(1) A condition monitoring device for an extracted-gas compression system according to at least some embodiments of the present invention is a condition monitoring device for an extracted-gas compression system including a compressor which increases pressure of extracted gas, including:

a sensor for detecting a state quantity of the extracted gas flowing into the compressor;

an erosion progression level calculation unit for calculating an erosion progression level of the compressor on the basis of the state quantity of the extracted gas; and

a service life evaluation unit for evaluating a service life of the compressor on the basis of the erosion progression level of the compressor.

In the configuration (1) described above, the service life of the compressor is evaluated on the basis of the erosion progression level of the compressor calculated on the basis of the state quantity of the extracted gas. Thus, the service life of the compressor can be appropriately evaluated as a part of state monitoring for the extracted-gas compression system even when the state quantity of the extracted gas changes.

With this service life of the compressor as a result of the evaluation thus obtained, the maintenance plan for the compressor can be appropriately designed, whereby a higher yielding performance of the plant as a whole can be achieved with an unoperated period of the plant shortened.

(2) In some embodiments, in the condition monitoring device for an extracted-gas compression system with the configuration (1) described above, the state quantity includes at least one of: a particle size of a foreign matter in the extracted gas; a concentration of the foreign matter in the extracted gas; and a hardness of the foreign matter.

In the configuration (2), the service life of the compressor can be appropriately evaluated on the basis of the state quantity of the extracted gas such as the particle size, the concentration, or the hardness of a foreign matter in the extracted gas.

(3) In some embodiments, in the condition monitoring device for an extracted-gas compression system with the configuration (1) or (2) described above, the erosion progression level calculation unit is configured to calculate the erosion progression level on the basis of a flowrate of the extracted gas as well as the state quantity of the extracted gas.

In the configuration (3) described above, the flowrate of the extracted gas can be more appropriately evaluated on the basis of the state quantity of the extracted gas as well as the flowrate of the extracted gas flowing into the compressor.

(4) In some embodiments, the condition monitoring device for an extracted-gas compression system, with any one of the configurations (1) to (3) described above, further includes an operation state switching unit configured to switch an operation state of the compressor between a rated operation state and a service life lengthening operation state involving a slower erosion progression level of the compressor than the rated operation state, on the basis of a result of the evaluation by the service life evaluation unit.

In the configuration (4) described above, the service life of the compressor can be controlled on the basis of the result of evaluating the service life of the compressor, with the operation state of the compressor switched between the rated operation state and the service life lengthening operation state.

(5) In some embodiments, in the condition monitoring device for an extracted-gas compression system with the configuration (4) described above, the service life lengthening operation state involves a less rotational speed of the compressor than the rated operation state.

The erosion progression speed of the compressor is proportional to the Nth power (N>1) of the flowrate of the extracted gas, and thus is sensitive to the rotational speed of the compressor (thus, the flowrate of the extracted gas).

In this regard, in the configuration (4) described above, the rotational speed of the compressor in the service life lengthening operation state is set to be less than that in the rated operation state. Thus, the erosion progression speed of the compressor can be effectively reduced, and the service life of the compressor can be effectively lengthened.

(6) In some embodiments, in the condition monitoring device for an extracted-gas compression system with the configuration (4) or (5) described above, the operation state switching unit is configured to determine an operation condition in the service life lengthening operation state on the basis of: a difference between the erosion progression level at a current time point and a tolerable value of the erosion progression level; and a remaining time period between the current time point and a next regularly scheduled inspection.

In the configuration (6) described above, the operation condition in the service life lengthening operation state is determined on the basis of the remaining time period to the between the current time point and the next regularly scheduled inspection. Thus, the number of maintenance times can be reduced while preventing the operation of the compressor from stopping, with the subsequent service life of the compressor lengthened.

(7) In some embodiments, in the condition monitoring device for an extracted-gas compression system,

the extracted-gas compression system further includes a motor for driving the compressor, and

the condition monitoring device further includes:

a reference correlation acquisition unit for acquiring a known reference correlation for sample gas between supplied power to the motor and an output of the compressor, the sample gas having a known reference state quantity;

an output correction unit for correcting an actual output of the compressor on the basis of the state quantity of the extracted gas detected by the sensor to calculate a corrected output value of the compressor corresponding to supplied power to the motor in a case where the extracted gas has the reference state quantity; and

an abnormality detection unit for detecting an abnormality in the extracted-gas compression system on the basis of a result of comparing a relationship between the supplied power to the motor and the corrected output value with the reference correlation.

(7′) A condition monitoring device for an extracted-gas compression system according to at least some embodiments of the present invention is, regardless of the presence or absence of the configuration (1) described above, is a

condition monitoring device for an extracted-gas compression system including a compressor which increases pressure of extracted gas and a motor for driving the compressor, including:

a reference correlation acquisition unit for acquiring a known reference correlation for sample gas between supplied power (motor input) to the motor and an output of the compressor, the sample gas having a known reference state quantity;

an output correction unit for correcting an actual output of the compressor on the basis of the state quantity of the extracted gas detected by the sensor to calculate a corrected output value of the compressor corresponding to supplied power to the motor in a case where the extracted gas has the reference state quantity; and

an abnormality detection unit for detecting an abnormality in the extracted-gas compression system on the basis of a result of comparing a relationship between the supplied power to the motor and the corrected output value with the reference correlation.

In the configuration (7) or (7′), the actual output of the compressor is corrected on the basis of a result of detecting the state quantity of the extracted gas. Thus, the corrected output value of the compressor is calculated that corresponds to the motor supplied power in the case where the extracted gas has the reference state quantity (the known state quantity of the extracted gas). The corrected output value of the compressor thus obtained is based on the same state quantity (reference state quantity) as the sample gas. Thus, the relationship between the motor supplied power and the corrected output value can be appropriately compared with the reference correlation without being affected by the change in the state quantity of the extracted gas. All things considered, an abnormality as a sign of a failure in the extracted-gas compression system can be detected even when the operation range of the compressor is inconsistent due to the state quantity of the extracted gas.

(8) In some embodiments, in the condition monitoring device for an extracted-gas compression system, with the configuration (7) or (7′) described above, further includes an abnormality locating unit configured to determine whether the abnormality has occurred in the compressor or the motor on the basis of a result of comparing the actual output of the motor corresponding to the supplied power to the motor with a designed output value, when the abnormality detection unit detects the abnormality in the extracted-gas compression system.

In the configuration (7) or (7′) described above, when the abnormality detection unit detects an abnormality in the extracted-gas compression system, it is most likely either in the compressor or the motor that the abnormality has occurred.

Thus, in the configuration (8) described above, whether the abnormality has occurred in the compressor or the motor on the basis of a result of comparing the motor actual output corresponding to the supplied power to the motor with the designed output value.

For example, when the difference between the motor actual output corresponding to the motor supplied power and the designed output value is within a tolerable range, the abnormality is likely to have occurred in the compressor and not in the motor. On the other hand, when the difference between the motor actual output corresponding to the motor supplied power and the designed output value is outside the tolerable range, the abnormality is likely to have occurred in the motor and not in the compressor. In this manner, the location where the abnormality has occurred can be identified on the basis of a result of comparing the motor actual output corresponding to the motor supplied power with the designed output value.

(9) In some embodiments, in the condition monitoring device for an extracted-gas compression system with the configuration (7), (7′), or (8) described above, the abnormality detection unit is configured to determine that the abnormality has occurred in the extracted-gas compression system, when a difference between a reference output of the compressor corresponding to the supplied power to the motor in the reference correlation and the corrected output value calculated by the output correction unit exceeds a first threshold.

In the configuration (9) described above, the difference between the reference output of the compressor corresponding to the supplied power to the motor in the reference correlation and the corrected output value calculated by the output correction unit is compared with the first threshold. Thus, whether an abnormality has occurred in the extracted-gas compression system can be highly precisely determined even when the operation range of the compressor is inconsistent due to the change in the state quantity of the extracted gas.

(10) In some embodiments, in the condition monitoring device for an extracted-gas compression system according to (7), (7′), or (8) described above, the abnormality detection unit is configured to determine that the abnormality has occurred in the extracted-gas compression system, when a deviation ratio of the corrected output value calculated by the output correction unit with respect to a reference output of the compressor corresponding to the supplied power to the motor in the reference correlation exceeds a second threshold.

In the configuration (10) described above, the deviation ratio of the corrected output value calculated by the output correction unit with respect to the reference output of the compressor corresponding to the supplied power to the motor in the reference correlation is compared with the second threshold. Thus, whether an abnormality has occurred in the extracted-gas compression system can be highly precisely determined even when the operation range of the compressor is inconsistent due to the change in the state quantity of the extracted gas.

(11) In some embodiments, in the condition monitoring device for an extracted-gas compression system according to (7), (7′), or (8) described above, the abnormality detection unit is configured to determine that the abnormality has occurred in the extracted-gas compression system, when a period in which a deviation rate of the corrected output value with respect to the reference output or a difference between a reference output of the compressor corresponding to the supplied power to the motor in the reference correlation and the corrected output value calculated by the output correction unit exceeds a third threshold, continues for a predetermined time period or longer.

In the configuration (11) described above, on the basis of the difference between the corrected output value and the reference output of the compressor, or on the basis of whether the period in which the deviation rate of the corrected output value with respect to the reference output exceeds the third threshold continues for the predetermined time period or longer, whether an abnormality has occurred in the extracted-gas compression system can be highly precisely determined even when the operation range of the compressor is inconsistent due to the change in the state quantity of the extracted gas.

(12) In some embodiments, in the condition monitoring device for an extracted-gas compression system according to (7), (7′), or (8) described above, the abnormality detection unit is configured to determine that the abnormality has occurred in the extracted-gas compression system, when speed of increase in a deviation ratio of the corrected output value from the reference output or speed of increase in a difference between a reference output of the compressor corresponding to the supplied power to the motor in the reference correlation and the corrected output value calculated by the output correction unit exceeds a fourth threshold.

In the configuration (12) described above, by comparing the difference between the reference output of the output of the compressor and the corrected output value, or the speed of increase in the deviation ratio of the corrected output value from the reference output, with the fourth threshold, whether an abnormality has occurred in the extracted-gas compression system can be highly precisely determined even when the operation range of the compressor is inconsistent due to the change in the state quantity of the extracted gas.

(13) An extracted-gas compression system according to at least some embodiments of the present invention includes:

a compressor for increasing pressure of extracted gas; and

the condition monitoring device with any one of the configurations (1) to (12) described above.

In the configuration (13) described above, the condition monitoring device with any one of the configurations (1) to (12) described above is provided. Thus, the service life of the compressor can be evaluated appropriately as described above, whereby the extracted-gas compression system can be efficiently operated.

(14) A condition monitoring method for an extracted-gas compression system including a compressor which increases pressure of extracted gas, according to at least some embodiments of the present invention, includes:

a state quantity detection step of detecting a state quantity of the extracted gas flowing into the compressor;

an erosion progression level calculation step of calculating an erosion progression level of the compressor on the basis of the state quantity of the extracted gas; and

a service life evaluation step of evaluating a service life of the compressor on the basis of the erosion progression level of the compressor.

In the method (14) described above, the service life of the compressor is evaluated on the basis of the erosion progression level of the compressor calculated on the basis of the state quantity of the extracted gas. Thus, the service life of the compressor can be appropriately evaluated as a part of state monitoring for the extracted-gas compression system even when the state quantity of the extracted gas changes.

With this service life of the compressor as a result of the evaluation thus obtained, the maintenance plan for the compressor can be appropriately designed, whereby a higher yielding performance of the plant as a whole can be achieved with an unoperated period of the plant shortened.

(15) In some embodiments, the condition monitoring method for an extracted-gas compression system according to (14) described above, wherein the state quantity includes at least one of: a particle size of a foreign matter in the extracted gas; a concentration of the foreign matter in the extracted gas; and a hardness of the foreign matter.

In the method (15) described above, the service life of the compressor can be appropriately evaluated on the basis of the state quantity of the extracted gas such as the particle size, the concentration, or the hardness of a foreign matter in the extracted gas.

(16) In some embodiments, the condition monitoring method for an extracted-gas compression system according to (14) or (15) described above, wherein the erosion progression level calculation step includes calculating the erosion progression level on the basis of a flowrate of the extracted gas as well as the state quantity of the extracted gas.

In the method (16) described above, the flowrate of the extracted gas can be more appropriately evaluated on the basis of the state quantity of the extracted gas as well as the flowrate of the extracted gas flowing into the compressor.

(17) In some embodiments, the condition monitoring method for an extracted-gas compression system according to any one of (14) to (16) described above, further comprising an operation state switching step of switching an operation state of the compressor between a rated operation state and a service life lengthening operation state involving a slower erosion progression level of the compressor than the rated operation state on the basis of a result of the evaluation in the service life evaluation step.

In the method (17) described above, the service life of the compressor can be controlled on the basis of the result of evaluating the service life of the compressor, with the operation state of the compressor switched between the rated operation state and the service life lengthening operation state.

(18) In some embodiments, in the condition monitoring method for an extracted-gas compression system according to (17) described above, the service life lengthening operation state involves a less rotational speed of revolutions of the compressor than the rated operation state.

In the method (18) described above, the rotational speed of the compressor in the service life lengthening operation state is set to be less than that in the rated operation state. Thus, the erosion progression speed of the compressor can be effectively reduced, and the service life of the compressor can be effectively lengthened.

(19) In some embodiments, in the condition monitoring method for an extracted-gas compression system according to (17) or (18) described above, the operation state switching step includes determining an operation condition in the service life lengthening operation state on the basis of: a difference between the erosion progression level at a current time point and a tolerable value of the erosion progression level; and a remaining time period between the current time point and a next regularly scheduled inspection.

In the method (19) described above, the operation condition in the service life lengthening operation state is determined on the basis of the remaining time period to the between the current time point and the next regularly scheduled inspection. Thus, the number of maintenance times can be reduced while preventing the operation of the compressor from stopping, with the subsequent service life of the compressor lengthened.

(20) In some embodiments, in the condition monitoring method for an extracted-gas compression system according to any one of (14) to (19) described above, the extracted-gas compression system further includes a motor for driving the compressor, and

the condition monitoring method further includes:

a state quantity detection step of detecting a state quantity of the extracted gas flowing into the compressor;

a reference correlation acquisition step of acquiring a known reference correlation for sample gas between supplied power to the motor and an output of the compressor, the sample gas having a known reference state quantity;

an output correction step of correcting an actual output of the compressor on the basis of the state quantity of the extracted gas detected in the state quantity detection step, and calculating a corrected output value of the compressor corresponding to supplied power to the motor in a case where the extracted gas has the reference state quantity; and

an abnormality detection step of detecting abnormality in the extracted-gas compression system on the basis of a result of comparing a relationship between the supplied power to the motor and the corrected output value with the reference correlation.

(20′) A condition monitoring method for an extracted-gas compression system, including a compressor which increases pressure of extracted gas and a motor for driving the compressor, according to at least some embodiments of the present invention, may or may not include the steps in the method (14), and includes:

a state quantity detection step of detecting a state quantity of the extracted gas flowing into the compressor;

a reference correlation acquisition step of acquiring a known reference correlation for sample gas between supplied power to the motor and an output of the compressor, the sample gas having a known reference state quantity;

an output correction step of correcting an actual output of the compressor on the basis of the state quantity of the extracted gas detected in the state quantity detection step, and calculating a corrected output value of the compressor corresponding to supplied power to the motor in a case where the extracted gas has the reference state quantity; and

an abnormality detection step of detecting abnormality in the extracted-gas compression system on the basis of a result of comparing a relationship between the supplied power to the motor and the corrected output value with the reference correlation.

In the method (20) and (20′), the actual output of the compressor is corrected on the basis of a result of detecting the state quantity of the extracted gas. Thus, the corrected output value of the compressor is calculated that corresponds to the motor supplied power in the case where the extracted gas has the reference state quantity (the known state quantity of the extracted gas). The corrected output value of the compressor thus obtained is based on the same state quantity (reference state quantity) as the sample gas. Thus, the relationship between the motor supplied power and the corrected output value can be appropriately compared with the reference correlation without being affected by the change in the state quantity of the extracted gas. All things considered, an abnormality as a sign of a failure in the extracted-gas compression system can be detected even when the operation range of the compressor is inconsistent due to the state quantity of the extracted gas.

(21) In some embodiments, the condition monitoring method for an extracted-gas compression system according to the method (20) or (20′) described above, further includes an abnormality locating step of determining whether the abnormality has occurred in the compressor or the motor on the basis of a result of comparing the actual output of the motor corresponding to the supplied power to the motor with a designed output value, when the abnormality in the extracted-gas compression system is detected in the abnormality detection step.

In the method (21) described above, whether the abnormality has occurred in the compressor or the motor on the basis of a result of comparing the motor actual output corresponding to the supplied power to the motor with the designed output value.

For example, when the difference between the motor actual output corresponding to the motor supplied power and the designed output value is within a tolerable range, the abnormality is likely to have occurred in the compressor and not in the motor. On the other hand, when the difference between the motor actual output corresponding to the motor supplied power and the designed output value is outside the tolerable range, the abnormality is likely to have occurred in the motor and not in the compressor. In this manner, the location where the abnormality has occurred can be identified on the basis of a result of comparing the motor actual output corresponding to the motor supplied power with the designed output value.

### Advantageous Effects

In at least one embodiment of the present invention, the service life of the compressor is evaluated on the basis of the erosion progression level of the compressor calculated on the basis of the state quantity of the extracted gas. Thus, the service life of the compressor can be appropriately evaluated as a part of state monitoring for the extracted-gas compression system even when the state quantity of the extracted gas changes.

### BRIEF DESCRIPTION OF DRAWINGS

FIG. 1 is a diagram illustrating a schematic configuration of an extracted-gas compression system according to one embodiment.

FIG. 2 is a graph illustrating an example of erosion progression level for describing a designed service life and an actual service life.

FIG. 3 is a graph illustrating an example of erosion progression level for describing an estimated service life.

FIG. 4 is a graph illustrating a rated operation state and service life lengthening operation state.

FIG. 5 is a flowchart illustrating a condition monitoring method for an extracted-gas compression system according to one embodiment.

FIG. 6 is a diagram illustrating a schematic configuration of an extracted-gas compression system according to one embodiment.

FIG. 7 is a diagram illustrating input and output of a motor and a compressor according to one embodiment.

FIG. 8 is a graph illustrating an example of an actual measurement value and a corrected value with respect to a reference correlation.

FIG. 9 is a graph illustrating an example of a chronological change in a difference between the reference output and the corrected output value.

FIG. 10 is a graph illustrating an example of a chronological change in a deviation ratio of the corrected output value from the reference output.

FIG. 11 is a diagram illustrating input and output of a motor and a compressor according to another embodiment.

FIG. 12 is a graph illustrating a relationship between a motor input and a motor output.

FIG. 13 is a flowchart illustrating a method for detecting an abnormality in an extracted-gas compression system according to one embodiment.

### DETAILED DESCRIPTION

Embodiments of the present invention will now be described in detail with reference to the accompanying drawings. It is intended, however, that dimensions, materials, shapes, relative positions and the like of components described in the embodiments shall be interpreted as illustrative only and not limitative of the scope of the present invention.

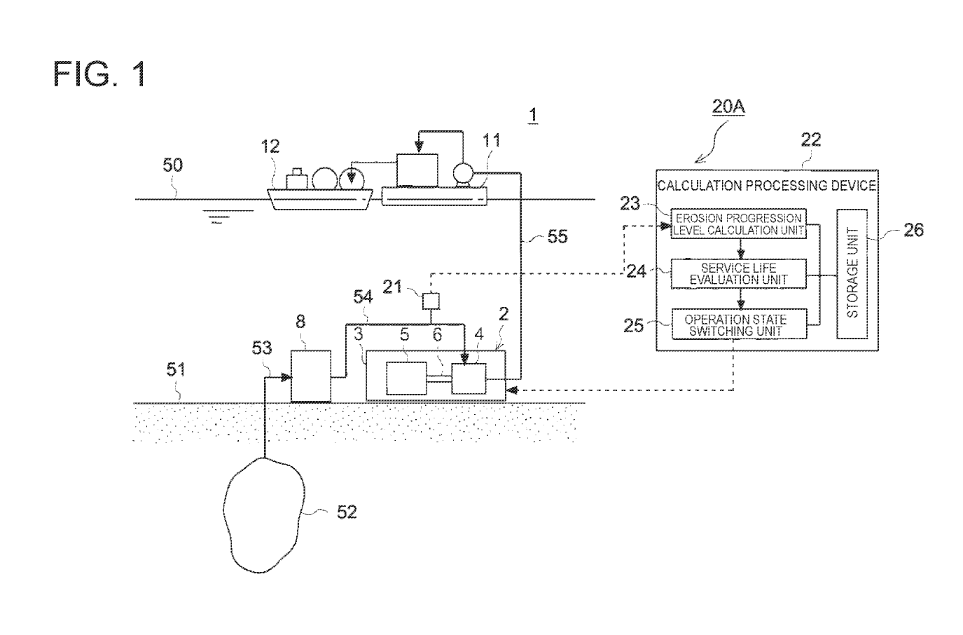

First of all, a schematic configuration of an extracted-gas compression system 1 according to one embodiment is described with reference to FIG. 1.

As illustrated in FIG. 1, the extracted-gas compression system 1 is mainly configured to compress (increase the pressure of) extracted gas 54 in a resource extracted from a gas field or an oil field underground or under the sea floor, and to send the resource with pressure to, for example, an external processing facility, storage facility, or the like. The extracted-gas compression system 1 with the example configuration illustrated in FIG. 1 is used in an offshore plant, and includes a compressor 4 that is installed on a sea floor 51 and compresses the extracted gas 54 extracted from a gas field 52 under the sea floor 51.

Although not elaborated in the figure, the extracted-gas compression system 1 may have other example configurations in which gas extracted from other floors of, for instance, a lake or a river, or in which the compressor 4 is installed above water of, for instance, sea or a lake, or on the ground. Furthermore, the extracted-gas compression system 1 may compress gas extracted from underground.

The extracted-gas compression system 1 according to one embodiment includes: a gas-liquid separator 8; the compressor 4 connected to the gas-liquid separator 8; and a motor 5 for driving the compressor 4.

The gas-liquid separator 8 is configured to separate a liquid component from liquid-containing gas (extracted gas) 53 extracted from the gas field 52 under the sea floor 51. In many cases, gas buried under the sea floor 51 is extracted in a state of including a liquid component. In these cases, the gas-liquid separator 8 separates the liquid component from the liquid-containing gas 53, so that liquid cracked gas (extracted gas) 54, including a gas component only, is sent to the compressor 4. The gas-liquid separator 8 may be omitted depending on the property of the liquid-containing gas 53.

The compressor 4 is connected to an output shaft 6 of the motor 5, and is configured to be driven by the motor 5 to increase the pressure of liquid. The compressor 4 and the motor 5 may form a motor integral type compressor 2 with a single casing 3 incorporating the compressor 4 and the motor 5. The motor integral type compressor 2 may have the casing 3 with a gas tight structure and thus can achieve easy protection of the compressor 4 and the motor 5 against corrosion due to sea water, when used in a case where the compressor 4 is installed on the sea floor 51 as illustrated in the figure. Furthermore, although not elaborated in the figure, the motor integral type compressor 2 can achieve downsizing of the compressor 4 and the motor 5 and thus can save space on a platform 11 with a limited space, when used in a case where the compressor 4 is installed on the platform 11 floating on the sea.

In the extracted-gas compression system 1 described above, the liquid-containing gas (extracted gas) 53 extracted from the gas field 52 under the sea floor 51 is introduced into the gas-liquid separator 8 and then separated into a gas component and a liquid component in the gas-liquid separator 8.

The liquid cracked gas (extracted gas) 54 as a result of separating the liquid component by the gas-liquid separator 8, is introduced to the compressor 4, connected to the gas-liquid separator 8, to have the pressure increased by the compressor 4. The liquid component separated from the extracted gas 53 by the gas-liquid separator 8 is sent to another processing line, and thus is omitted in the figure.

Compressed gas 55 discharged from the compressor 4 is set to the outside of the extracted-gas compression system 1. For example, as illustrated in the figure, the compressed gas 55 is temporarily stored in a tank placed on the platform 11 floating on a sea surface 50, and then is transported with a tanker 12.

Generally, the compressor 4 has a specification determined on the basis of an operation range (use condition) of the compressor 4. More specifically, the specification of the compressor 4 is determined in accordance with a designed service life taking into account an estimated predetermined use condition, as represented by a type and a flowrate of gas flowing into the compressor 4, compressor rotational speed, and the like.

Unfortunately, an extracted-gas compression system 1 having the above configuration deals with extracted gas 54 with various properties, and thus the operation range (use condition) of the compressor 4 is inconsistent. Thus, the compressor 4 might have a service life shorter than the designed service life. In particular, in a case where the extracted-gas compression system 1 used in an offshore plant as illustrated in FIG. 1, when the compressor 4 fails, preparation for the new compressor takes time and thus the plant becomes inoperable during the preparation.

Thus, in the present embodiment, an evaluation of the service life of the compressor 4 is performed with a condition monitoring device 20A, as a part of state monitoring for the extracted-gas compression system 1.

The condition monitoring device 20A according to one embodiment includes: a sensor 21 for detecting a state quantity of the extracted gas 54; and a calculation processing device 22 configured to perform calculation for the evaluation of the service life of the compressor 4 by using a detection value from the sensor 21.

A specific example configuration of each component of the condition monitoring device 20A is described below.

The sensor 21 is configured to detect the state quantity of the extracted gas 54 flowing into the compressor 4. Specifically, the sensor 21 is disposed on a gas line, establishing connection between the gas-liquid separator 8 and the compressor 4, and detects the state quantity of the extracted gas 54 as a result of separating the liquid component.

The state quantity of the extracted gas 54 may include at least one of a particle size of a foreign matter in the extracted gas 54, the concentration of the foreign matter in the extracted gas, and hardness of the foreign matter.

The calculation processing device 22 includes an erosion progression level calculation unit 23, a service life evaluation unit 24, and a storage unit 26.

For example, the calculation processing device 22 includes a central processing unit (CPU), a random access memory (RAM), a read only memory (ROM), and/or other computer-readable recording media (not illustrated). A series of processing processes for implementing various functions described later is stored in a recording medium or the like in a form of a program. Functions of components of the calculation processing device 22 are implemented when the CPU loads the program onto the RAM or the like, and executes information processing/calculation processing. The calculation processing device 22 may be disposed in a location remote from the extracted-gas compression system 1.

The erosion progression level calculation unit 23 is configured to calculate erosion progression level of the compressor 4 on the basis of the state quantity of the extracted gas 54. As described above, the state quantity of the extracted gas 54 may include at least one of the particle size of a foreign matter in the extracted gas 54, the concentration of the foreign matter in the extracted gas, and the hardness of the foreign matter. The erosion progression level calculation unit 23 may be configured to calculate the erosion progression level on the basis of the state quantity of the extracted gas 54 and further on the basis of a flowrate of the extracted gas 54.

The service life evaluation unit 24 is configured to evaluate the service life of the compressor 4 on the basis of the erosion progression level of the compressor 4.

For example, the storage unit 26 is configured to store therein various types of data such as the state quantity of the extracted gas 54 detected by the sensor 21.

For example, the erosion progression level calculation unit 23 calculates erosion progression speed W in each time period on the basis of the following Formula (1), and calculates erosion progression level E representing cumulation of the erosion up to a certain time point, on the basis of the erosion progression speed W.

W=K·U^{N}·d^{M}·H^{L} (1)

As described above, in the formula, W represents the erosion progression speed (an erosion amount per unit time) of the compressor 4, and thus indicates the erosion progression level E per unit time. In the formula, U represents a flowrate of the extracted gas 54 flowing in the compressor 4, d represent an average particle size of the foreign matter in the extracted gas 54, and H represents the hardness of the foreign matter in the extracted gas 54. K, L, M, N are constants, which are determined on the basis of a system including the compressor 4.

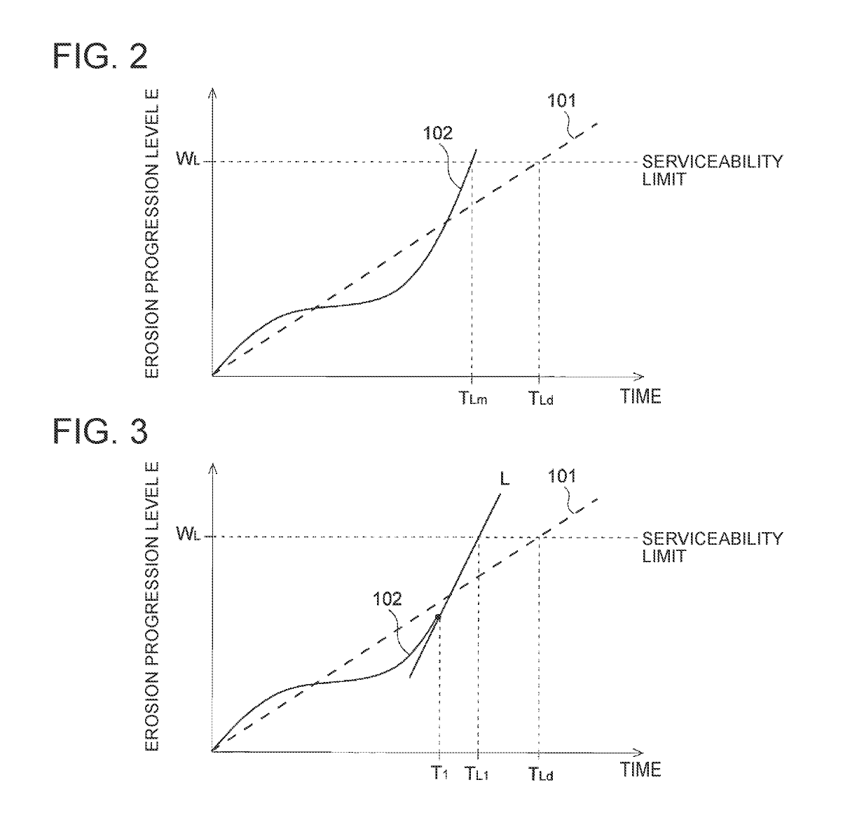

FIG. 2 is a graph illustrating an example of the erosion progression level, for describing a designed service life and an actual service life.

In the graph, a straight line 101 represents the erosion progression level E estimated under a condition expected at the time of designing. Under an assumption that the state quantity of the extracted gas 54 is constant, the erosion progression speed W calculated on the basis of Formula (1) described above is constant in any time period. Thus, the straight line 101 is obtained by cumulating values of the erosion progression level E (erosion progression speed W) in each time period.

A curved line 102 represents the erosion progression level E calculated while the compressor 4 is actually operating. This indicates that the erosion progression speed W calculated by Formula (1) described above differs among the time periods, due to the change in the state quantity over time, while the compressor 4 is actually operating. Thus, generally, the erosion progression level E, as a cumulation of the erosion progression speed W in each time period calculated by Formula (1) described above, is represented by the curved line 102 instead of the straight line.

The service life of the compressor 4 may be defined as a time period required for the erosion progression level E to reach a serviceability limit W_{L} of the compressor 4. In such a condition, time T_{Ld} required for the straight line 101 to reach the erosion progression level W_{L} represents the designed service life, and time T_{Lm} required for the curved line 102 to reach the erosion progression level W_{L} represents the actual service life. In the graph illustrated in FIG. 2, the actual service life T_{Lm} is shorter than the designed service life T_{Ld}. When the compressor 4 is used under a rated operation until the designed service life T_{Ld} expires, a failure might occur. Thus, a service life closer to the actual service life T_{Lm} than the designed service life T_{Ld} needs to be estimated before the actual service life T_{Lm} expires. Alternatively, if the actual service life T_{Lm} is much longer than the designed service life T_{Ld}, a regularly scheduled inspection can be performed at a longer interval, whereby a maintenance cost can be reduced.

Thus, the service life evaluation unit 24 evaluates the service life of the compressor 4 on the basis of the erosion progression level E of the compressor 4.

FIG. 3 is a graph illustrating an example of erosion progression, for describing the estimated service life. For example, as illustrated in FIG. 3, the service life evaluation unit 24 calculates a tangential line L of the curved line 102 at a current time T₁. When the slope of the tangential line L is larger than that of the straight line 101, an estimated service life T_{L1} is set at a time point corresponding to an intersection between the tangential line L and the serviceability limit erosion progression level W_{L} (that is, at a time point where the tangential line L reaches the erosion progression W_{L}). The designed service life T_{Ld} may be used as the estimated service life, when the time point T_{L1}, corresponding to the intersection between the tangential line L and the serviceability limit erosion progression level W_{L}, is after the time point corresponding to the designed service life T_{Ld}.

The method of estimating the service life on the basis of the erosion progression level E is not limited to the one described above.

In the configuration described above, the service life evaluation is performed for the compressor 4 on the basis of the erosion progression level of the compressor 4 calculated on the basis of the state quantity of the extracted gas 54, and thus can be appropriately performed even when the state quantity of the extracted gas 54 changes.

With the service life of the compressor 4 as a result of the evaluation obtained in the manner described above, the maintenance plan of the compressor 4 can be appropriately designed, whereby a yield of the plant as a whole can be improved with the unoperated period of the plant shortened.

At least one of the particle size of a foreign matter in the extracted gas 54, the concentration of the foreign matter in the extracted gas, and the hardness of the foreign matter is used as the state quantity of the extracted gas 54. Thus, the service life evaluation can be appropriately performed for the compressor 4 on the basis of the state quantity of the extracted gas 54 such as the particle size, the concentration, the hardness, and the like of the foreign matter in the extracted gas 54.

The erosion progression level calculation unit 23 uses not only the state quantity of the extracted gas 54 but also uses the flowrate of the extracted gas flowing into the compressor 4, and thus can more appropriately perform the service life evaluation for the compressor 4.

The calculation processing device 22 may further include an operation state switching unit 25.

The operation state switching unit 25 is configured to switch the operation state of the compressor 4 between the rated operation state and the service life lengthening operation state featuring a slower erosion progression level in the compressor 4, compared with the rated operation state.

The service life lengthening operation state may be achieved by setting the rotational speed of the compressor 4 lower than that in the rated operation state.

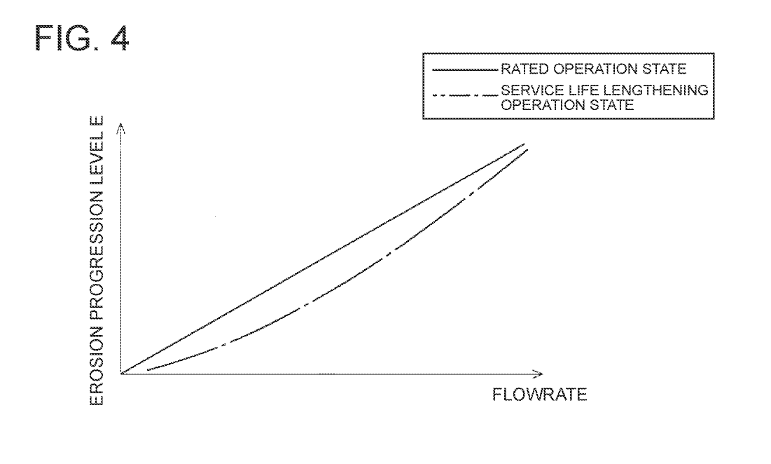

FIG. 4 is a graph illustrating the rated operation state and the service life lengthening operation state. The figure illustrates a relationship between the erosion progression level E and the flowrate of the extracted gas 54 in each operation state of the compressor 4, with a solid line representing the rated operation state and a dashed-dotted line representing the service life lengthening operation state.

The erosion progression speed W of the compressor 4 is proportional to the Nth power (N>1) of the flowrate of the extracted gas 54, as indicated by Formula (1) described above, and thus is sensitive to the rotational speed (that is, the flowrate of the extracted gas) of the compressor 4.
Thus, the service life lengthening operation state features the slower rotational speed of the compressor 4 compared with the rated operation state, whereby the erosion progression speed of the compressor 4 is effectively lowered to effectively increase the service life of the compressor 4. For example, when the rotational speed of the compressor 4 is lowered by 50%, the erosion progression speed can be less than 50%, whereby the service life lengthening operation state featuring a less wearing can be achieved.

The service life lengthening operation state can also be achieved by changing an operation condition other than the rotational speed. For example, a configuration may be employed in which a filter (not illustrated) for removing foreign matters is provided on an upstream side of the compressor 4. In such a configuration, the service life lengthening operation state is achieved by using a filter with a higher filtering performance compared with that used in the rated operation state to reduce the size of the particle in the extracted gas 54.

The operation state switching unit 25 may be configured to determine the operation condition in the service life lengthening operation state on the basis of a difference between the erosion progression level and a tolerable value of the erosion progression level (serviceability limit erosion progression level W_{L}) at the current time point and the remaining time period between the current time point and a next regularly scheduled inspection.

In this configuration, the operation condition in the service life lengthening operation state is determined on the basis of the remaining time period to the next regularly scheduled inspection. Thus, the number of maintenance times can be reduced while preventing the operation of the compressor 4 from stopping, with the subsequent service life of the compressor 4 lengthened.

For example, the operation condition may be changed on the basis of Formula (1) described above, when the remaining time period between the current time point and a next regularly scheduled inspection is longer than time obtained by dividing the difference between the erosion progression level at the current time point and the serviceability limit erosion progression level W_{L} by the slope of the tangential line L (see FIG. 3) of the curved line 102 at the current time T₁. In such a configuration, the slope of the tangential line L (see FIG. 3) of the curved line 102 at the current time T₁ is corrected on the basis of the influence of the change in the operation condition, and a virtual line indicating the erosion progression level after the change in the operation condition may be calculated. Then, the operation condition may be changed in such a manner that the time point corresponding to the intersection between the virtual line and the serviceability limit erosion progression level W_{L} is set to be at or after the next regularly scheduled inspection timing. When the time obtained by dividing the difference by the slope of the tangential line L of the curved line 102 is identical to or longer than the remaining time period between the current time point and the next regularly scheduled inspection, the operation condition used at the current time point may be maintained.

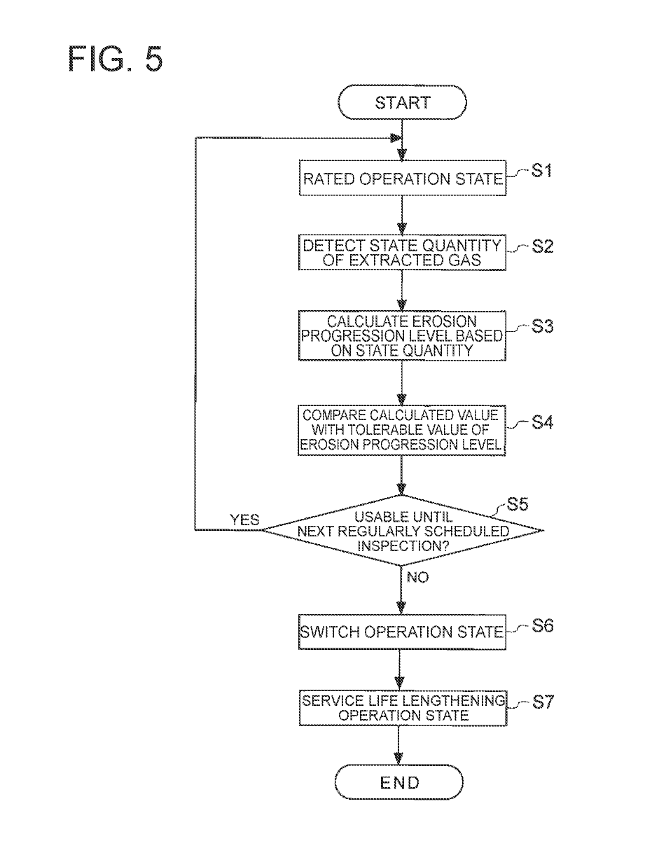

Next, a condition monitoring method for the extracted-gas compression system 1 according to one embodiment is described with reference to FIG. 5. In the description below, the reference numerals used in the description with reference to FIG. 1 is used as appropriate.

In one embodiment, the condition monitoring method for the extracted-gas compression system 1 includes: a state quantity detection step (for example, S2) for detecting the state quantity of the extracted gas 54 flowing into the compressor 4; an erosion progression level calculation step (for example, S3) for calculating the erosion progression level of the compressor 4 on the basis of the state quantity of the extracted gas 54; and a service life evaluation step (for example, S4) for evaluating the service life of the compressor 4 on the basis of the erosion progression level of the compressor 4.

Specifically, under a normal condition, the compressor 4 is operated in the rated operation state in step S1, and the state quantity of the extracted gas 54 is detected in step S2. For example, the state quantity includes at least one of the particle size of a foreign matter in the extracted gas 54, the concentration of the foreign matter in the extracted gas 54, and the hardness of the foreign matter. Then, in step S3, the erosion progression level of the compressor 4 is calculated on the basis of the state quantity of the extracted gas 54. In the erosion progression level calculation step, the erosion progression level may be calculated on the basis of the state quantity of the extracted gas 54, and further on the basis of the flowrate of the extracted gas. For example, in step S3, the erosion progression speed W may be calculated by using Formula (1) described above, and the erosion progression level E may be calculated by using the erosion progression speed W. Then, in step S4, the service life of the compressor 4 is evaluated on the basis of the erosion progression level of the compressor 4.

In this method, the service life evaluation is performed for the compressor 4 on the basis of the erosion progression level of the compressor 4 calculated on the basis of the state quantity of the extracted gas 54. Thus, the service life evaluation for the compressor 4 can be appropriately performed even when the state quantity of the extracted gas 54 changes.

Furthermore, with the result of the evaluation of the service life of the compressor 4, the maintenance plan of the compressor 4 can be appropriately designed. Thus, the yield of the plant as a whole can be improved with the unoperated period of the plant shortened.

The condition monitoring method for the extracted-gas compression system 1 may further include an operation state switching step (for example, S5, S6). In this step, the operation state of the compressor 4 is switched between the rated operation state and the service life lengthening operation state, featuring a slower erosion progression of the compressor than that in the rated operation state, on the basis of the result of the evaluation obtained by the service life evaluation step. For example, the service life lengthening operation state is achieved by setting the rotational speed of the compressor 4 to be smaller than that in the rated operation state.

In this method, the service life of the compressor 4 can be controlled on the basis of a result of evaluating the service life of the compressor 4, with the operation state of the compressor 4 switched between the rated operation state and the service life lengthening operation state.

Specifically, in step S4, a calculated value of the erosion progression level at the current time point is compared with the tolerable value of the erosion progression level (serviceability limit erosion progression level W_{L}), the resultant difference and the remaining time period between the current time point and a next regularly scheduled inspection are used for determining the service life lengthening operation condition. In step S5, whether the compressor 4 can be used until the next regularly scheduled inspection is determined. When the compressor 4 is determined to be usable until the next regularly scheduled inspection, the compressor 4 continues to be operated with the rated operation state maintained. When the compressor 4 is not determined to be usable until the next regularly scheduled inspection, the operation state is switched in step S6 and the compressor 4 continues to be operated with the operation state switched to the service life lengthening operation state in step S7.

In this method, the operation condition in the service life lengthening operation state is determined on the basis of the remaining time period to the next regularly scheduled inspection. Thus, the number of maintenance times can be reduced, while preventing the operation of the compressor 4 from stopping with the subsequent service life of the compressor 4 lengthened.

In the embodiment described above, the service life evaluation is performed on the compressor 4 on the basis of the erosion progression level of the compressor 4 calculated based on the state quantity of the extracted gas 54. Thus, the service life evaluation can be appropriately performed on the compressor 4 even when the state quantity of the extracted gas 54 changes.

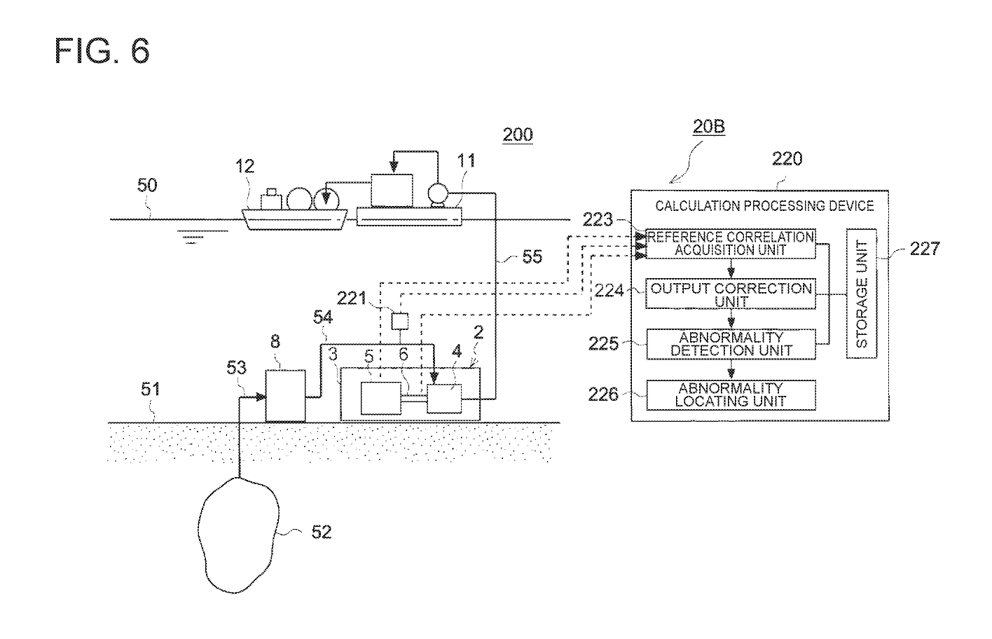

Next, condition monitoring devices and condition monitoring methods for extracted-gas compression systems according to other embodiments are described with reference to FIG. 6 to FIG. 13.

FIG. 6 is a diagram illustrating a schematic configuration of an extracted-gas compression system 200 according to one of other embodiments.

As illustrated in FIG. 6, the extracted-gas compression system 200 includes: the gas-liquid separator 8; the compressor 4 connected to the gas-liquid separator 8; and the motor 5 for driving the compressor 4, as in the case of the extracted-gas compression system 1. The gas-liquid separator 8, the compressor 4, and the motor 5 each has the configuration in the extracted-gas compression system 1 described above. The gas-liquid separator 8 may be omitted depending on the property of the liquid-containing gas 53.

In FIG. 6, the configurations that are the same as those in the extracted-gas compression system 1 are denoted with the reference numerals that are the same as those in FIG. 1. The configurations are the same as those described above, and thus the description thereof is omitted herein.

Generally, the compressor 4 has a specification determined based on an operation range (use condition) of the compressor 4. More specifically, the specification of the compressor 4 is determined in accordance with a designed service life by taking into account an estimated predetermined use condition, as represented by a type and a flowrate of gas flowing into the compressor 4, compressor rotational speed, and the like.

Unfortunately, an extracted-gas compression system 200 having the above configuration deals with extracted gas 54 with various properties, and thus the operation range (use condition) of the compressor 4 is inconsistent. Thus, the compressor 4 might have a service life shorter than the designed service life. In particular, when the compressor 4 fails in the extracted-gas compression system 200 used in an offshore plant as illustrated in FIG. 1, preparation for the new compressor takes time, and thus the plant becomes inoperable.

In view of the above, a condition monitoring device 20B is provided in the present embodiment. The condition monitoring device 20B can accurately detect an abnormality in the extracted-gas compression system 200 even when the operation range of the compressor 4 is inconsistent.

The condition monitoring device 20B according to some embodiments include: a sensor 221 for detecting the state quantity of the extracted gas 54; and a calculation processing device 220 configured to perform calculation for detecting an abnormality of the compressor 4 by using the detection value from the sensor 221.

A specific example configuration of each component of the condition monitoring device 20B is described below.

The sensor 221 is configured to detect the state quantity of the extracted gas 54 flowing into the compressor 4. Specifically, the sensor 221 is disposed on a gas line, establishing connection between the gas-liquid separator 8 and the compressor 4, and detects the state quantity of the extracted gas 54 as a result of separating the liquid component.

The state quantity of the extracted gas 54 may include at least one of density, temperature, and pressure of the extracted gas 54.

The calculation processing device 220 includes a reference correlation acquisition unit 223, an output correction unit 224, an abnormality detection unit 225, and a storage unit 227.

For example, the calculation processing device 220 includes a central processing unit (CPU), a random access memory (RAM), a read only memory (ROM), and/or other computer-readable recording media (not illustrated). A series of processing processes for implementing various functions described later is stored in a recording medium or the like in a form of a program. Functions of components of the calculation processing device 220 are implemented when the CPU loads the program onto the RAM or the like, and executes information processing/calculation processing. The calculation processing device 220 may be disposed in a location remote from the extracted-gas compression system 200.

The reference correlation acquisition unit 223 is configured to acquire a known reference correlation for sample gas between supplied power to the motor 5 and an output from the compressor 4. As described above, the sample gas has a known reference state quantity. The reference correlation acquisition unit 223 may acquire the known reference correlation from the storage unit 227 or from an input unit (unillustrated).

The output correction unit 224 is configured to correct an actual output from the compressor 4 based on the state quantity of the extracted gas 54 detected by the sensor 221, to calculate a corrected output value of the compressor 4 corresponding to the supplied power to the motor 5 under a condition where the extracted gas 54 has a reference state quantity.

The abnormality detection unit 225 detects the abnormality in the extracted-gas compression system 200, on the basis of a result of a comparison between the reference correlation and a relationship between the corrected output value and the supplied power to the motor 5.

For example, the storage unit 227 stores therein the known reference correlation for the sample gas between the supplied power to the motor 5 and the output of the compressor 4. The storage unit 227 stores therein the known reference correlation acquired in advance. For example, the known reference correlation may be acquired through experiments using the sample gas, acquired from simulations and the like, or may be acquired from empirically obtained past data. The known reference correlation thus acquired may be stored in the storage unit 227 through a communication line or a storage medium, or through an input from the input unit of the calculation processing device 22.

The storage unit 227 stores therein at least one reference correlation. As described later, the abnormality detection is performed as follows. Specifically, the output of the compressor 4 is corrected on the basis of the state quantity corresponding to the reference correlation, and then the reference correlation is compared with the corrected output value of the compressor 4. Thus, the storage unit 227 basically needs to store therein at least one reference correlation.

Alternatively, the storage unit 227 may store therein the known reference correlation between the supplied power to the motor 5 and the output of the compressor 4, based on each of a plurality of types of sample gas with different state quantities.

The known reference correlation is described below in detail.

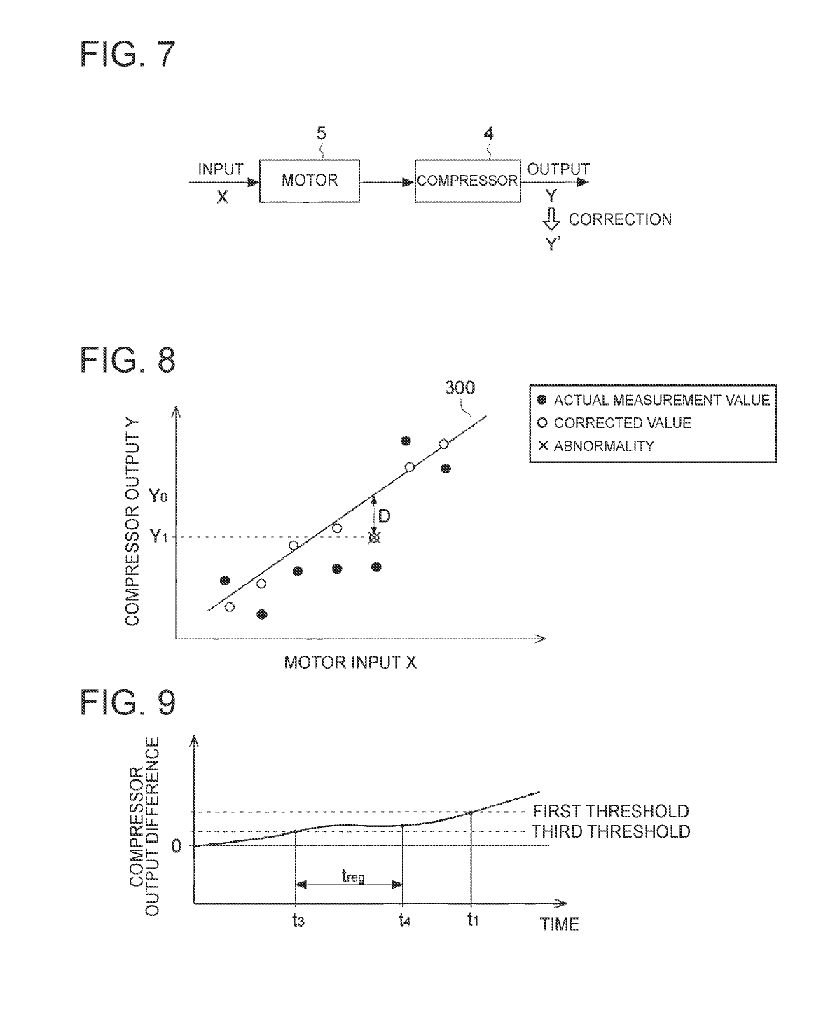

FIG. 7 is a diagram illustrating an input and an output of the motor 5 and the compressor 4 according to one embodiment. FIG. 8 is a graph illustrating an example of actual measurement values and corrected values with respect to a reference correlation 300.

As illustrated in FIG. 7, the motor 5 drives the compressor 4 with an output Y, upon being supplied with power (motor input X).

In an example illustrated in FIG. 8, a straight line 300 represents the known reference correlation between the supplied power (motor input X) to the motor 5 and the output Y of the compressor 4, for the sample gas having the known reference state quantity.

In FIG. 8, apart from the known reference correlation 300, the actual measurement values and the corrected values of the output of the compressor 4 are further plotted.

The actual measurement value of the output of the compressor 4 is an actual output Y₁ of the compressor 4 corresponding to the actual supplied power (motor input X) to the motor 5. The output Y of the compressor 4 can be obtained with the following Formula (1):

$$\begin{matrix}[ Math . 1 ] & \\ Y = K \cdot {P}_{1} \cdot Q \cdot \{ {( \begin{matrix}{P}_{2} \\ {P}_{1}\end{matrix} )}^{m} 1 \} & ( 1 )\end{matrix}$$

where Y represents the output (kW) of the compressor 4, Q represents a volume (m³/s) of gas before compression, P₁ represents pressure (N/m²) before the compression, P₂ represents pressure (N/m²) after the compression, and K and m are constants.

The actual output Y₁ of the compressor 4 is acquired by detecting the volume of gas before the compression, the pressure before the compression, and the pressure after the compression with various sensors and the like.

As illustrated in the figure, the actual measurement value (the relationship between the motor input X and the actual output Y₁ of the compressor) of the compressor 4 thus obtained is deviated in many cases from the known reference correlation 300. One possible reason for this is that the state quantity of the extracted gas 54 passing through the compressor 4 changes. Thus, a simple comparison between the known reference correlation 300 and the actual measurement value of the compressor 4 only leads to an abnormality detection with low accuracy.

Thus, in some embodiments, a corrected output value Y′ is calculated by correcting actual output Y₁ of the compressor 4, in the output correction unit 224, on the basis of the state quantity of the extracted gas 54.

The corrected output value Y′ of the compressor 4 can be obtained with the following Formula (2), in an example where the state quantity is the density:

$$\begin{matrix}[ Math . 2 ] & \\ {Y}^{′} = {Y}_{1} \cdot ( \frac{{ρ}_{0}}{ρ} ) & ( 2 )\end{matrix}$$

where Y′ represents the corrected output value (kW) of the compressor 4, Y₁ represents the actual output (kW) of the compressor 4, ρ₀ represents density of the sample gas, and p represents the density of the extracted gas 54 detected by the sensor 221.

Formula (2) indicates the impact of the density as the state quantity on the output of the compressor 4. In other embodiments, the corrected output value Y′ of the compressor 4 is calculated by using a formula or a table indicating an impact of another state quantity (for example, temperature, pressure, or the like of the exhaust gas 54) on the output of the compressor 4 that may change while the extracted-gas compression system 200 is in operation.

When there is no abnormality in the motor 5 or the compressor 4, the corrected values, based on the corrected output value Y′ of the compressor 4 thus obtained and the input X of the motor 5, are plotted approximately along the known reference correlation 300 regardless of the change in the state quantity of the extracted gas 54.

On the other hand, the corrected output value Y′ of the compressor 4 largely deviated from the known reference correlation 300 may be regarded as an abnormality.

Thus, in some embodiment, the abnormality detection unit 225 detects am abnormality in the extracted-gas compression system 200, on the basis of a result of comparing the relationship, between the supplied power (motor input X) to the motor 5 and the corrected output value Y′ from the compressor 4, with the reference correlation 300.

In the condition monitoring device 20B having the configuration described above, the actual output Y₁ from the compressor 4 is corrected based on a result of detecting the state quantity of the extracted gas 54. Thus, the corrected output value Y′ of the compressor 4, corresponding to the motor supplied power (motor input X) in a case where the extracted gas 54 has the reference state quality (the known state quantity of the sample gas), is calculated. The corrected output value Y′ of the compressor 4 thus obtained is based on the same state quantity (reference state quantity) as the sample gas. Thus, the relationship, between the motor supplied power and the corrected output value Y′, and the reference correlation 300 can be appropriately compared with each other without being affected by the change in the state quantity of the extracted gas 54. All things considered, the abnormality as a sign of the failure of the extracted-gas compression system 200 can be detected, even when the operation range of the compressor 4 is in consistent due to the change in the state quantity of the extracted gas 54.

The abnormality detection by the abnormality detection unit 225 is described below in detail.

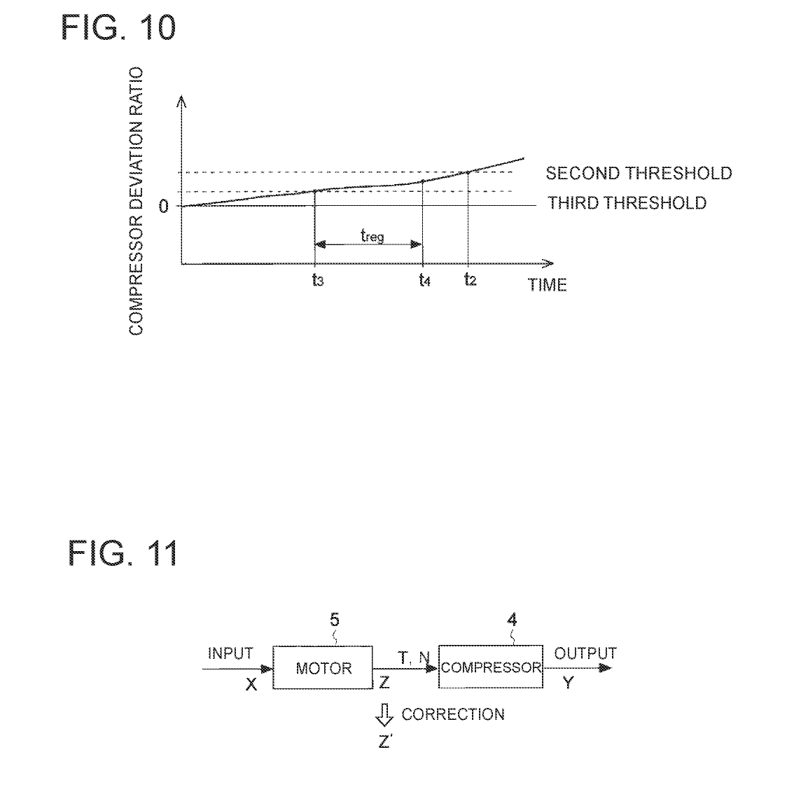

FIG. 9 is a graph illustrating an example of a chronological change in a difference D between the reference output Y₀ and the corrected output value Y′. FIG. 10 is a graph illustrating an example of the chronological change in a deviation ratio of the corrected output value Y′ with respect to the reference output Y₀. In the description below, the reference numerals in FIGS. 6 and 7 are used as appropriate. In the graphs illustrated in FIGS. 9 and 10, intermittently calculated values of the difference between the reference output Y₀ and the corrected output value Y′ or the chronological change in the deviation ratio of the corrected output value Y′ with respect to the reference output Y₀ are connected to each other to obtained curved lines indicating their change over time.

As illustrated in FIG. 9, in one embodiment, the abnormality detection unit 225 is configured to determine that an abnormality has occurred in the extracted-gas compression system 200, at a time point t₁ at which the difference D between the reference output Y₀ of the compressor 4 corresponding to the supplied power (motor input X) to the motor 5 and the corrected output value Y′ calculated by the output correction unit 224 in the reference correlation 300 (see FIG. 3) exceeds a first threshold. For example, it may be determined that an abnormality has occurred in the extracted-gas compression system 200 when the absolute value of the difference D between the reference output Y₀ of the compressor 4 and the corrected output value Y′ exceeds the first threshold. Alternatively, a positive first threshold and a negative first threshold with the same absolute value may be set. Thus, it may be determined that an abnormality has occurred in the extracted-gas compression system 200 when the absolute value of the difference D between the reference output Y₀ of the compressor 4 and the corrected output value Y′ exceeds the positive first threshold, or when the absolute value of the difference D between the reference output Y₀ of the compressor 4 and the corrected output value Y′ falls below the negative first threshold.

As described above, the difference D, between the reference output Y₀ of the compressor 4 corresponding to the motor supplied power (motor input X) determined on the basis of the reference correlation 300 (see FIG. 8) and the corrected output value Y′ calculated by the output correction unit 224, is compared with the first threshold. Thus, whether an abnormality has occurred in the extracted-gas compression system 200 can be accurately determined even when the operation range of the compressor 4 is inconsistent due to the change in the state quantity of the extracted gas 54.

In another embodiment, as illustrated in FIG. 10, the abnormality detection unit 225 is configured to determine that an abnormality has occurred in the extracted-gas compression system 200 at a time point t₂ at which the deviation ratio of the corrected output value Y′, calculated by the output correction unit 224, with respect to the reference output Y₀ of the compressor 4, corresponding to the supplied power (motor input X) to the motor 5 in the reference correlation 300 (see FIG. 8), exceeds a second threshold. The deviation ratio of the corrected output value Y′ may be a value obtained by dividing the difference D between the reference output Y₀ and the corrected output value Y′ by the reference output Y₀. For example, it may be determined that an abnormality has occurred in the extracted-gas compression system 200, when an absolute value of the deviation ratio of the corrected output value Y′ with respect to the reference output Y₀ of the compressor 4 exceeds the second threshold. Alternatively, a positive second threshold and a negative second threshold with the same absolute value may be set. It may be determined that an abnormality has occurred in the extracted-gas compression system 200, when the deviation ratio of the corrected output value Y′ with respect to the reference output Y₀ of the compressor 4 exceeds the positive second threshold or when the deviation ratio of the corrected output value Y′ with respect to the reference output Y₀ of the compressor 4 falls below the negative second threshold.

As described above, the deviation ratio of the corrected output value Y′, calculated by the output correction unit 224, with respect to the reference output Y₀ of the compressor 4, corresponding to the supplied power (motor input X) to the motor 5 and determined based in the reference correlation 300 (see FIG. 8), is compared with the second threshold. Thus, whether an abnormality has occurred in the extracted-gas compression system 200 can be accurately determined even when the operation range of the compressor 4 is inconsistent due to the change in the state quantity of the extracted gas 54.

In still another embodiment, as illustrated in FIGS. 9 and 10, the abnormality detection unit 225 is configured to determine that an abnormality has occurred in the extracted-gas compression system 200, when a period in which the difference between the reference output Y₀ of the compressor 4, corresponding to the supplied power (motor input X) to the motor 5 in the reference correlation 300 (see FIG. 8), and the corrected output value Y′, calculated by the output correction unit 224, or the deviation ratio of the corrected output value Y′ with respect to the reference output Y₀ exceeds a third threshold continues for a predetermined time period t_{reg} or longer. Specifically, the abnormality detection unit 225 counts an elapsed time after a time point t₃, which is a time point at which the difference, between the reference output Y₀ of the compressor 4 and the corrected output value Y′, or the deviation ratio of the corrected output value Y′ with respect to the reference output Y₀ has exceeded the third threshold, then the abnormality detection unit 225 determines that an abnormality has occurred at a time point t₄ at which the elapsed time reaches the predetermined time period t_{reg}.

Whether an abnormality has occurred can be determined with the method described above by using two types of thresholds such as the first threshold and the third threshold illustrated in FIG. 9 or the second threshold and the third threshold illustrated in FIG. 10. In such a configuration, the third threshold may be smaller than the first threshold or the second threshold.

All things considered, even when the operation range of the compressor 4 is inconsistent due to the change in the state quantity of the extracted gas 54, whether an abnormality has occurred in the extracted-gas compression system 200 can be accurately determined, based on whether the predetermined time period t_{reg} is equal to or shorter than the period in which the difference between the reference output Y₀ of the compressor 4 and the corrected output value Y′ or the deviation ratio of the corrected output value Y′ with respect to the reference output Y₀ exceeds the third threshold.

The abnormality detection unit 225 may be configured to determine that an abnormality has occurred in the extracted-gas compression system 200, when a speed of increase in the difference between the reference output Y₀ of the compressor 4, corresponding to the supplied power (motor input X) to the motor 5 in the reference correlation 300 and the corrected output value Y′, calculated by the output correction unit 224, or the deviation ratio of the corrected output value Y′ with respect to the reference output Y₀, exceeds a fourth threshold (not illustrated). Specifically, the abnormality detection unit 225 determines that an abnormality has occurred in the extracted-gas compression system 200 when a value obtained by differentiating the difference (see FIG. 4) between the reference output Y₀ of the compressor 4 and the corrected output value Y′ by time or a value obtained by differentiating the deviation ratio (see FIG. 5) of the corrected output value Y′ with respect to the reference output Y₀ by time exceeds the fourth threshold.

Thus, even when the operation range of the compressor 4 is inconsistent due to the change in the state quantity of the extracted gas 54, whether an abnormality has occurred in the extracted-gas compression system 200 can be accurately determined, by comparing the speed of increase in the difference, between the reference output Y₀ of the compressor 4, or the deviation ratio of the corrected output value Y′ with respect to the reference output Y₀, with the fourth threshold.

The condition monitoring device 20B described above may further have the following configuration.

In another embodiment, the calculation processing device 22 of the condition monitoring device 20B further includes an abnormality locating unit 26 (see FIG. 6).

The abnormality locating unit 26 is configured to determine whether the abnormality has occurred in the compressor 4 or the motor 5 on the basis of a result of comparing an actual output Z₁ corresponding to the supplied power (motor input X) to the motor 5 and a designed output value Z₀, when the abnormality detection unit 225 detects an abnormality in the extracted-gas compression system 200.

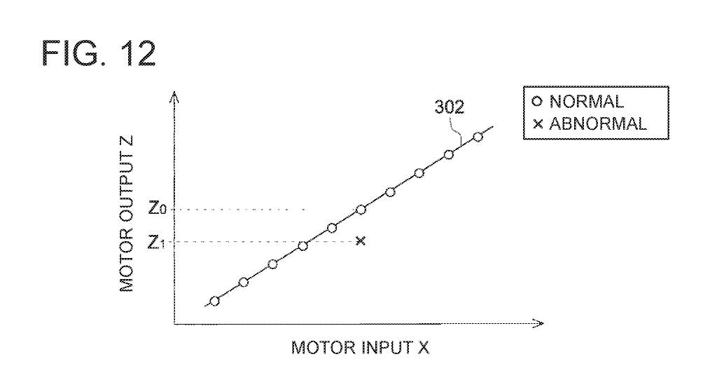

FIG. 11 is a diagram illustrating input and output of the motor 5 and the compressor 4 according to another embodiment. FIG. 12 is a graph illustrating a relationship between the motor input X and the motor output Z.

As illustrated in FIG. 11 the motor 5 is driven by an output (motor output) Z by receiving supplied power (motor input X). The motor output Z is input to the compressor 4 as rotational energy with torque T and rotational speed N, and the compressor 4 is driven by the output Y.

For example, the motor output Z is calculated through the following Formula (3): [Math. 3]

Z=k·T·N (3)

where Z represents motor output (kW), T represents torque [kg·m(N/m/9.8)], and N rotational speed (min⁻¹). Here, for acquiring an actual output Z₁ of the motor 5, the torque and the rotational speed of the motor 5 are detected by a sensor and the like.

In a graph in FIG. 12, a straight line 302 represents a designed output value Z₀ of the motor 5 corresponding to the supplied power (motor input X) to the motor 5. The abnormality locating unit 26 determines whether the abnormality has occurred in the compressor 4 or the motor 5, on the basis of a result of comparing the actual output Z₁ of the motor 5 corresponding to the supplied power (motor input) to the motor 5 and the designed output value Z₀.

For example, when the difference between the motor actual output Z₁ corresponding to the motor supplied power and the designed output value Z₀ is within a tolerable range, the abnormality is likely to have occurred in the compressor 4 and not in the motor 5. On the other hand, when the difference between the motor actual output Z₁ corresponding to the motor supplied power and the designed output value Z₀ is out of the tolerable range, the abnormality is likely to have occurred in the motor 5 and not in the compressor 4. In this manner, the location where the abnormality has occurred can be identified on the basis of a result of comparing the motor actual output Z₁ corresponding to the motor supplied power with the designed output value Z₀.

The abnormality locating unit 26 may use a corrected output value Z′ obtained by correcting the actual output Z₁ with the state quantity, as the actual output Z₁ of the motor 5. In this configuration, the abnormality locating unit 26 determines whether the abnormality has occurred in the compressor 4 or the motor 5, on the basis of a result of comparing the corrected output value Z′, obtained by correcting the actual output Z₁ with the state quantity, with the designed output value Z₀.

For example, the corrected output value Z′ of the motor 5 is calculated with the following Formula (4) when the state quantity is the density:

$$\begin{matrix}[ Math . 4 ] & \\ {Z}^{′} = {Z}_{1} \cdot ( \frac{{ρ}_{0}}{ρ} ) & ( 4 )\end{matrix}$$

where Z′ represents the motor corrected output value (kW), Z₁ represents actual output of the motor (kW), ρ₀ represents the density of the sample gas, and p represents the density of the extracted gas 54 detected by the sensor 221.

By thus determining where the abnormality has occurred on the basis of a result of comparing the corrected output value Z′, obtained by correcting the actual output Z₁ of the motor 5 with the state quantity, with the designed output value Z₀, the location where the abnormality has occurred can be accurately determined regardless of the change in the state quantity of the extracted gas 54.

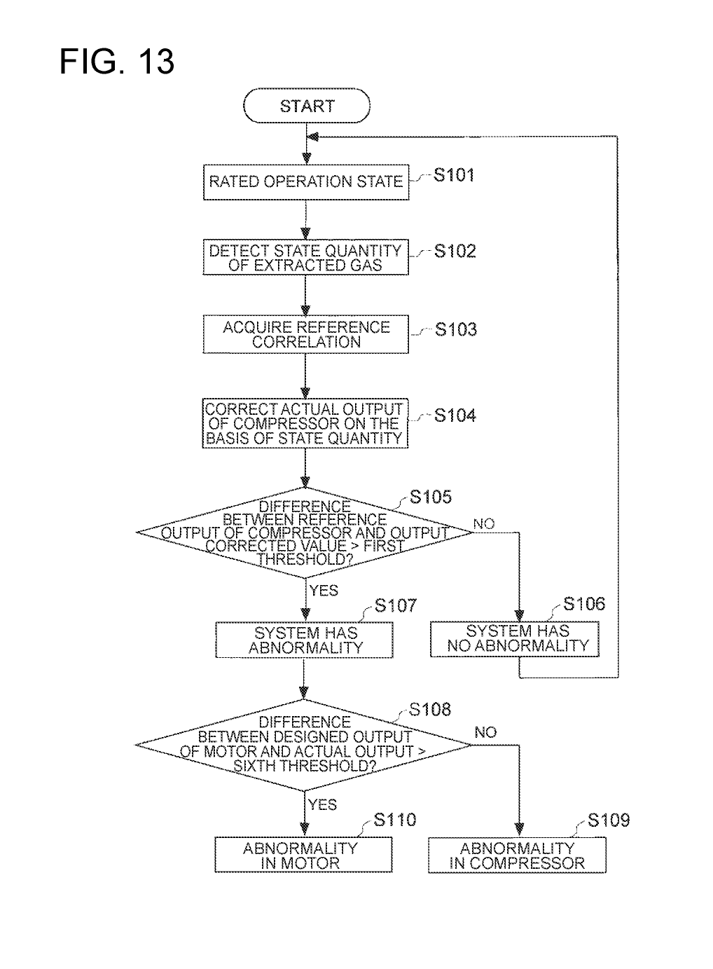

Next, a method for detecting an abnormality in the extracted-gas compression system 200 is described with reference to FIG. 13. In the description below, reference numerals in FIGS. 6 to 12 are used as appropriate.

As illustrated in FIG. 13, in step S101, the motor 5 and the compressor 4 operate in the rated operation state. In step S102 (state quantity detection step), the sensor 221 detects the state quantity of the extracted gas 54 (for example, density, temperature, pressure, or the like of the extracted gas 54) flowing in the compressor 4. In step S103 (reference correlation acquisition step), the known reference correlation 300 between the supplied power (motor input X) to the motor 5 and the reference output Y of the compressor 4, relative to the sample gas having the known reference state quantity, is acquired. In step S103, for example, the known reference correlation 300 may be read from the storage unit 227.

Then, in step S104 (output correction step), the actual output Y₁ of the compressor 4 is corrected on the basis of the state quantity of the extracted gas 54 detected by the sensor 221. Thus, the corrected output value Y′ of the compressor 4 corresponding to the supplied power (motor input X) to the motor 5 in the case where the extracted gas 54 has the reference state quantity is calculated. For example, the corrected output value Y′ of the compressor 4 is obtained by correcting the actual output Y₁ of the compressor 4, obtained by Formula (1) described above, with Formula (2) described above.

Then, in steps S105 to S107 (abnormality detection steps), the abnormality in the extracted-gas compression system 200 is detected on the basis of a result of comparing the relationship between the supplied power (motor input X) to the motor 5 and the corrected output value Y′ of the compressor 4, as well as the reference correlation 300.

For example, in step S105, whether the difference D between the reference output Y₀ of the compressor 4 corresponding to the supplied power to the motor 5 on the reference correlation 300 and the corrected output value Y′ exceeds the first threshold is determined. When the difference D between the reference output Y₀ of the compressor 4 and the corrected output value Y′ does not exceed the first threshold, it is determined in step S106 that the extracted-gas compression system 200 has no abnormality. Thus, the processing returns to step S101, and the rated operation state is maintained. On the other hand, when the difference D between the reference output Y₀ of the compressor 4 and the corrected output value Y′ exceeds the first threshold, it is determined in step S107 that an abnormality has occurred in the extracted-gas compression system 200.

Then, the following steps may be executed.

When it is determined that the abnormality has occurred in the extracted-gas compression system 200 in the processing proceeds to steps S108 to step S110 (abnormality locating steps), whether the abnormality has occurred in the compressor 4 or the motor 5 is determined on the basis of a result of comparing the actual output Z₁ of the motor 5 corresponding to the supplied power (motor input X) to the motor 4 with the designed output value Z₀.

For example, in step S108, a difference between the actual output Z₁ of the motor 5 and the designed output value Z₀ is compared with a fifth threshold. When the difference between the actual output Z₁ of the motor 5 and the designed output value Z₀ is smaller than the fifth threshold, it is determined in step S109 that an abnormality has occurred in the compressor 4. On the other hand, when the difference between the actual output Z₁ of the motor 5 and the designed output value Z₀ exceeds the fifth threshold, it is determined in step S110 that the abnormality has occurred in the motor 5. Alternatively, in the abnormality locating step, the deviation ratio of the designed output value Z₀ with respect to the actual output Z₁ of the motor 5 may be compared with a sixth threshold.

As described above, in the present embodiment, an abnormality as sign of a failure of the extracted-gas compression system 200 can be detected, even when the operation range of the compressor 4 is inconsistent due to the change in the state quantity of the extracted gas 54.

In one embodiment, the extracted-gas compression system 200 illustrated in FIG. 6 includes the condition monitoring device 20B. More specifically, the extracted-gas compression system 200 includes: the compressor 4 for increasing the pressure of the extracted gas 54; the motor 5 for driving the compressor 4; and the condition monitoring device 20B described above.

Thus, an abnormality as a sign of a failure of the extracted-gas compression system 200 can be detected even when the operation range of the compressor 4 is inconsistent due to the change in the state quantity of the extracted gas 54. Thus, the extracted-gas compression system 200 can be prevented from falling in a long inoperable state due to a sudden failure. All things considered, gas drillers can enjoy a higher yield.

The present invention is not limited to the embodiment described above, and includes a mode obtained by modifying the embodiment described above and a mode obtained by appropriately combining the modes.

For example, the expressions used herein that mean relative or absolute arrangement, such as “in a direction”, “along a direction”, in parallel with”, “orthogonal with”, “center”, “concentrically”, and coaxially mean not only exactly what they refer to but also, for instance, a state of relative displacement with a tolerance or by an angle or distance that is small enough to achieve the same level of functionality.

For example, the expressions used herein that mean things are equivalent to each other, such as “the same”, “equivalent”, and “uniform”, mean not only exactly equivalent states but also a state with a tolerance or a difference that is small enough to achieve the same level of functionality.

For example, expressions that represent shapes, such as quadrangles and cylinders, mean not only what they refer to in a geometrically strict sense but also shapes having some irregularities, chamfered portions, or the like that can provide the same level of functionality.

The expressions “including”, “comprising”, and “provided with” one component are not exclusive expressions that exclude other components.

### REFERENCE SIGNS LIST

1 Extracted-gas compression system
2 Motor integral type compressor
3 Casing
4 Compressor
5 Motor
6 Output shaft
8 Gas-liquid separator
11 Platform
12 Tanker
20 (20A, 20B) Condition monitoring device
21, 221 Sensor
22, 220 Calculation processing device
23 Erosion progression level calculation unit
24 Service life evaluation unit
25 Operation state switching unit
26 Storage unit
50 Sea surface
51 Sea floor
52 Gas field
223 Reference correlation acquisition unit
224 Output correction unit
225 Abnormality detection unit
226 Abnormality locating unit
227 Storage unit

1. A condition monitoring device for an extracted-gas compression system including a compressor which increases pressure of extracted gas, the condition monitoring device comprising:
a sensor for detecting a state quantity of the extracted gas flowing into the compressor;
an erosion progression level calculation unit for calculating an erosion progression level of the compressor on the basis of the state quantity of the extracted gas; and
a service life evaluation unit for evaluating a service life of the compressor on the basis of the erosion progression level of the compressor.

2. The condition monitoring device for an extracted-gas compression system according to claim 1, wherein the state quantity includes at least one of: a particle size of a foreign matter in the extracted gas; a concentration of the foreign matter in the extracted gas; and a hardness of the foreign matter.

3. The condition monitoring device for an extracted-gas compression system according to claim 1, wherein the erosion progression level calculation unit is configured to calculate the erosion progression level on the basis of a flowrate of the extracted gas as well as the state quantity of the extracted gas.

4. The condition monitoring device for an extracted-gas compression system according to claim 1, further comprising an operation state switching unit configured to switch an operation state of the compressor between a rated operation state and a service life lengthening operation state involving a slower erosion progression level of the compressor than the rated operation state, on the basis of a result of the evaluation by the service life evaluation unit.

5. The condition monitoring device for an extracted-gas compression system according to claim 4, wherein the service life lengthening operation state involves a less rotational speed of the compressor than the rated operation state.

6. The condition monitoring device for an extracted-gas compression system according to claim 4, wherein the operation state switching unit is configured to determine an operation condition in the service life lengthening operation state on the basis of: a difference between the erosion progression level at a current time point and a tolerable value of the erosion progression level; and a remaining time period between the current time point and a next regularly scheduled inspection.

7. The condition monitoring device for an extracted-gas compression system according to claim 1, wherein the extracted-gas compression system further includes a motor for driving the compressor,
the condition monitoring device further comprising:
a reference correlation acquisition unit for acquiring a known reference correlation for sample gas between supplied power to the motor and an output of the compressor, the sample gas having a known reference state quantity;
an output correction unit for correcting an actual output of the compressor on the basis of the state quantity of the extracted gas detected by the sensor to calculate a corrected output value of the compressor corresponding to supplied power to the motor in a case where the extracted gas has the reference state quantity; and
an abnormality detection unit for detecting an abnormality in the extracted-gas compression system on the basis of a result of comparing a relationship between the supplied power to the motor and the corrected output value with the reference correlation.

8. The condition monitoring device for an extracted-gas compression system according to claim 7 further comprising an abnormality locating unit configured to determine whether the abnormality has occurred in the compressor or the motor on the basis of a result of comparing the actual output of the motor corresponding to the supplied power to the motor with a designed output value, when the abnormality detection unit detects the abnormality in the extracted-gas compression system.

9. The condition monitoring device for an extracted-gas compression system according to claim 7, wherein the abnormality detection unit is configured to determine that the abnormality has occurred in the extracted-gas compression system, when a difference between a reference output of the compressor corresponding to the supplied power to the motor in the reference correlation and the corrected output value calculated by the output correction unit exceeds a first threshold.

10. The condition monitoring device for an extracted-gas compression system according to claim 7, wherein the abnormality detection unit is configured to determine that the abnormality has occurred in the extracted-gas compression system, when a deviation ratio of the corrected output value calculated by the output correction unit with respect to a reference output of the compressor corresponding to the supplied power to the motor in the reference correlation exceeds a second threshold.

11. The condition monitoring device for an extracted-gas compression system according to claim 7, wherein the abnormality detection unit is configured to determine that the abnormality has occurred in the extracted-gas compression system, when a period in which a deviation rate of the corrected output value with respect to the reference output or a difference between a reference output of the compressor corresponding to the supplied power to the motor in the reference correlation and the corrected output value calculated by the output correction unit exceeds a third threshold, continues for a predetermined time period or longer.

12. The condition monitoring device for an extracted-gas compression system according to claim 7, wherein the abnormality detection unit is configured to determine that the abnormality has occurred in the extracted-gas compression system, when speed of increase in a deviation ratio of the corrected output value from the reference output or speed of increase in a difference between a reference output of the compressor corresponding to the supplied power to the motor in the reference correlation and the corrected output value calculated by the output correction unit exceeds a fourth threshold.

13. An extracted-gas compression system comprising:
a compressor for increasing pressure of extracted gas; and
the condition monitoring device according to claim 1.

14. A condition monitoring method for an extracted-gas compression system including a compressor which increases pressure of extracted gas, the condition monitoring method comprising:
a state quantity detection step of detecting a state quantity of the extracted gas flowing into the compressor;
an erosion progression level calculation step of calculating an erosion progression level of the compressor on the basis of the state quantity of the extracted gas; and
a service life evaluation step of evaluating a service life of the compressor on the basis of the erosion progression level of the compressor.

15. The condition monitoring method for an extracted-gas compression system according to claim 14, wherein the state quantity includes at least one of: a particle size of a foreign matter in the extracted gas; a concentration of the foreign matter in the extracted gas; and a hardness of the foreign matter.

16. The condition monitoring method for an extracted-gas compression system according to claim 14, wherein the erosion progression level calculation step includes calculating the erosion progression level on the basis of a flowrate of the extracted gas as well as the state quantity of the extracted gas.

17. The condition monitoring method for an extracted-gas compression system according to claim 14, further comprising an operation state switching step of switching an operation state of the compressor between a rated operation state and a service life lengthening operation state involving a slower erosion progression level of the compressor than the rated operation state on the basis of a result of the evaluation in the service life evaluation step.

18. The condition monitoring method for an extracted-gas compression system according to claim 17, wherein the service life lengthening operation state involves a less rotational speed of the compressor than the rated operation state.

19. The condition monitoring method for an extracted-gas compression system according to claim 17, wherein the operation state switching step includes determining an operation condition in the service life lengthening operation state on the basis of: a difference between the erosion progression level at a current time point and a tolerable value of the erosion progression level; and a remaining time period between the current time point and a next regularly scheduled inspection.

20. The condition monitoring method for an extracted-gas compression system according to claim 14, wherein the extracted-gas compression system further includes a motor for driving the compressor,
the condition monitoring method further comprising:
a state quantity detection step of detecting a state quantity of the extracted gas flowing into the compressor;
a reference correlation acquisition step of acquiring a known reference correlation for sample gas between supplied power to the motor and an output of the compressor, the sample gas having a known reference state quantity;
an output correction step of correcting an actual output of the compressor on the basis of the state quantity of the extracted gas detected in the state quantity detection step, and calculating a corrected output value of the compressor corresponding to supplied power to the motor in a case where the extracted gas has the reference state quantity; and
an abnormality detection step of detecting abnormality in the extracted-gas compression system on the basis of a result of comparing a relationship between the supplied power to the motor and the corrected output value with the reference correlation.

21. The condition monitoring method for an extracted-gas compression system according to claim 20, further comprising an abnormality locating step of determining whether the abnormality has occurred in the compressor or the motor on the basis of a result of comparing the actual output of the motor corresponding to the supplied power to the motor with a designed output value, when the abnormality in the extracted-gas compression system is detected in the abnormality detection step.
